(19) United States
(12) Patent Application Publication
(10) Pub. No.: US 2018/0282868 A1
(43) Pub. Date: Oct. 4, 2018

(54) ASSEMBLY OF GAS INJECTOR AND CEILING FOR SEMICONDUCTOR PROCESSES AND FILM DEPOSITION

(71) Applicant: HERMES-EPITEK CORPORATION, Taipei City (TW)

(72) Inventor: Tsung-Hsien CHUANG, TAIPEI CITY (TW)

(73) Assignee: HERMES-EPITEK CORPORATION

(21) Appl. No.: 15/941,349

(22) Filed: Mar. 30, 2018

(30) Foreign Application Priority Data
Mar. 31, 2017 (TW) 106110963

(51) Int. Cl. C23C 16/455; H01L 21/67

(52) U.S. Cl. CPC C23C 16/45563; H01L 21/67017

(57) ABSTRACT

An assembly of a gas injector and a ceiling is used in a film deposition apparatus for semiconductor processes. The assembly comprises a gas injector and a ceiling. The gas injector comprises a gas passage portion, a flow injection portion in communication with the gas passage portion, and a plurality of fixation portions disposed on the flow injection portion. The ceiling comprises an engagement portion which contains and is interlocked with the fixation portions.

### CROSS-REFERENCE TO RELATED APPLICATION

This application claims priority from Taiwan Patent Application No. 106110963 filed on Mar. 31, 2017, which are hereby incorporated herein by reference in its entirety.

### BACKGROUND OF THE INVENTION

### 1. Field of the Invention

The invention relates to a vapor phase film deposition apparatus for forming a thin film on a semiconductor substrate, and particularly, to an assembly of a gas injector and a ceiling for semiconductor processes.

### 2. Description of Related Art

During the formation of a thin film on a semiconductor substrate, the reactor of a film deposition apparatus containing substrates utilizes a gas injector to feed gases, and the gas injector horizontally (or vertically) jets the reaction gasses above a susceptor for mixing. A film is then deposited on each substrate (e.g. a wafer) through physical or chemical reactions induced by heating. The gas injector is designed to horizontally inject the reaction gases and render the reaction gases uniformly distributed on the surface of the rotating substrate so as to form an even boundary layer on the surface of the substrate to facilitate the deposition of thin films.

FIG. 1 is a schematic cross-sectional diagram which shows the conventional reactor of a film deposition apparatus. A film deposition apparatus comprises a reactor 10 for the growth of a vapor phase deposition film. A closed chamber near vacuum is enclosed by chamber walls 11 and a chamber lid 12. A substrate sustaining member (or a substrate holder) 13 is disposed within the chamber, and is used to carry and hold at least one substrate (or wafer) W. A ceiling (i.e. an opposing face member) 14 is disposed opposing to the substrate sustaining member 13. A gas injector 15 is disposed at the center of the chamber lid 12. The gas injector 15 is used to guide and deliver gases such as a mixture of a source gas of H₂/N₂/group V element, a source gas of a group III element, and carrier gas and a source gas of H₂/N₂/group V element for semiconductor processes. The gas injector 15 horizontally jets the reaction gasses above a substrate W for mixing. A film is then deposited on each substrate W through physical or chemical reactions induced by heating.

During a deposition process, the temperature of the lower surface of the ceiling 14 attached to the upper side of the chamber lid 12 is preferably controlled to be around 300° C. in order to prevent particles from being accumulated on the lower surface of the ceiling 14 and falling from it to contaminate the wafers. Accordingly, the yield of a wafer is undesirably declined. There is a gap between the chamber lid 12 and the ceiling 14 mounted on the chamber lid 12. A mixture of gases which mixes several gases with various flow rates is introduced into the gap for the temperature control of the lower surface of the ceiling 14 so that the undesirable particles accumulated during the process are prevented from attaching to the lower surface of the ceiling 14. Hydrogen (H₂) and nitrogen (N₂) are used for such a design, and a gas mass flow controller (MFC) is further used to adjust the flow rates and mixture of gases. In addition, the gap between the ceiling 14 and the chamber lid 12 would be maintained at 0.1 mm and uniform anywhere. Therefore, the mixed gases can evenly pass the gap so as to achieve the preferable uniformity of the temperature.

There are several kinds of combinations of the ceilings and chamber lids. One of them needs to use a special tooling for fastening a fixing ring onto the surface of a ceiling. However, the tolerances and positions of the whole combination after assembly would be depended on the various operations acted by different equipment engineers. Another of the kinds utilizes four rotatable grapping hooks to grasp the corresponding interlock portions of the ceiling. Since the four rotatable grapping hooks are easily unbalanced when they are moved after holding the ceiling, the levelness of the ceiling accordingly gets worse.

Therefore, the uniformity of the flow of the foregoing mixed gases is also negatively affected.

In view of above, the semiconductor manufacturers are in very need of a vapor phase film deposition apparatus used to resolve the foregoing problems of the difficult assembling and uneven gas flow. Accordingly, the quality of the deposited thin film is improved.

### SUMMARY OF THE INVENTION

The present application provides an assembly of a gas injector and a ceiling for semiconductor processes. The efficiency of the assembling is increased by modifying the fastening mechanism of a ceiling with automatically mechanical aligning and interlocking parts.

The present application provides a vapor phase film deposition apparatus in order to improve the matching tolerances of the both assembled ceiling and chamber lid and the levelness of the ceiling.

In view of above aspects, the present application provides an assembly of a gas injector and a ceiling for semiconductor processes as an embodiment. The assembly comprises a gas injector comprising a gas passage portion, a flow injection portion in communication with the gas passage portion, and a plurality of fixation portions disposed on the flow injection portion; and a ceiling comprising an engagement portion which contains and is interlocked with the fixation portions and a plate combined with the engagement portion.

In another embodiment, each of the plurality of fixation portions includes a first positioning member and the engagement portion includes a plurality of second positioning members matched with the first positioning members. Each of the first positioning members is one of a location pin and a location hole, and each of the second positioning members is another.

In another embodiment, the engagement portion includes an opening and a compartment formed between the engagement portion and the plate. The plurality of fixation portions enter through the opening and is received within the compartment at corresponding locations after rotation.

In another embodiment, there is a trough hole at the center of the plate, and the trough hole allows a portion of the flow injection portion to pass therein.

In another embodiment, the plurality of fixation portions are radially protruded from the perimeter of the flow injection portion. The opening of the engagement portion is sized to match the flow injection portion and the protruded fixation portions.

The present application further provides a film deposition apparatus for semiconductor processes. The apparatus comprises a reactor, a gas injector comprising a gas passage portion, a flow injection portion in communication with the gas passage portion, and a plurality of fixation portions disposed on the flow injection portion; and a ceiling adjacent to the upper wall surface of the inner of the reactor, the ceiling comprising an engagement portion which contains and is interlocked with the fixation portions and a plate combined with the engagement portion.

In another embodiment, each of the plurality of fixation portions includes a first positioning member and the engagement portion includes a plurality of second positioning members matched with the first positioning members. Each of the first positioning members is one of a location pin and a location hole, and each of the second positioning members is another.

In another embodiment, the engagement portion includes an opening and a compartment formed between the engagement portion and the plate. The plurality of fixation portions enter through the opening and is received within the compartment at corresponding locations after rotation.

In another embodiment, there is a trough hole at the center of the plate, and the trough hole allows a portion of the flow injection portion to pass therein.

In another embodiment, the plurality of fixation portions are radially protruded from the perimeter of the flow injection portion. The opening of the engagement portion is sized to match the flow injection portion and the protruded fixation portions.

In another embodiment, the film deposition apparatus further composes a positioning fixing mechanism. The positioning fixing mechanism includes a joint fixing seat combined with the gas injector, a moving part mounted to the joint fixing seat, and a driving part letting the moving part have a linear movement. The film deposition apparatus further comprises a bush for the gas passage portion to relatively slide therein. The bush is mounted to the reactor outside.

In another embodiment, the film deposition apparatus further comprises a rotation mechanism. The rotation mechanism drives the gas injector to rotate so as to engage the plurality of fixation portions with the engagement portion.

### BRIEF DESCRIPTION OF THE DRAWINGS

In order to sufficiently understand the essence, advantages and the preferred embodiments of the present invention, the following detailed description will be more clearly understood by referring to the accompanying drawings.

FIG. 1 is a schematic cross-sectional diagram which shows the conventional reactor of a film deposition apparatus;

FIG. 2 is a schematic cross-sectional diagram which shows the reactor of a film deposition apparatus in accordance with an embodiment of the present application;

FIG. 3A illustrates a schematically perspective diagram of the gas injector as shown in FIG. 2;

FIG. 3B illustrates a schematically perspective diagram of the ceiling as shown in FIG. 2;

FIG. 4 is a top view of the engagement portion as shown in FIG. 3B;

FIG. 5A and FIG. 5B illustrate schematically perspective diagrams of a fixing portion in accordance with another embodiments of the present invention.

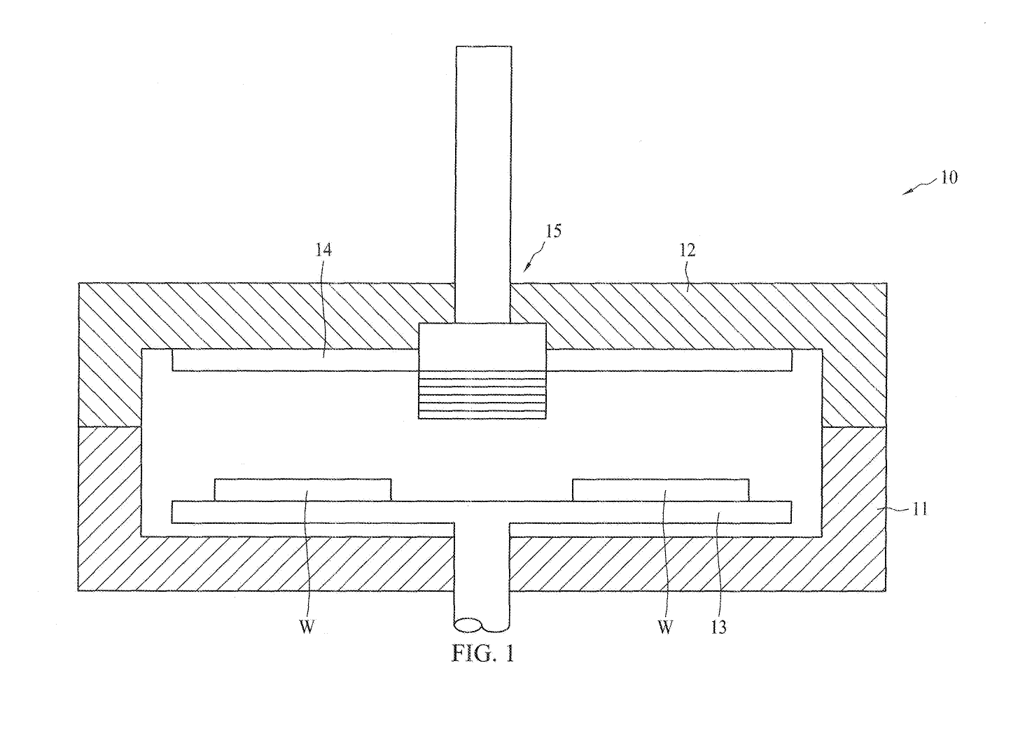

### DETAILED DESCRIPTION OF THE INVENTION

The following description shows the preferred embodiments of the present invention. The present invention is described below by referring to the embodiments and the figures. Thus, the present invention is not intended to be limited to the embodiments shown, but is to be accorded the principles disclosed herein. Furthermore, that various modifications or changes in light thereof will be suggested to persons skilled in the art and are to be included within the spirit and purview of this application and scope of the appended claims.

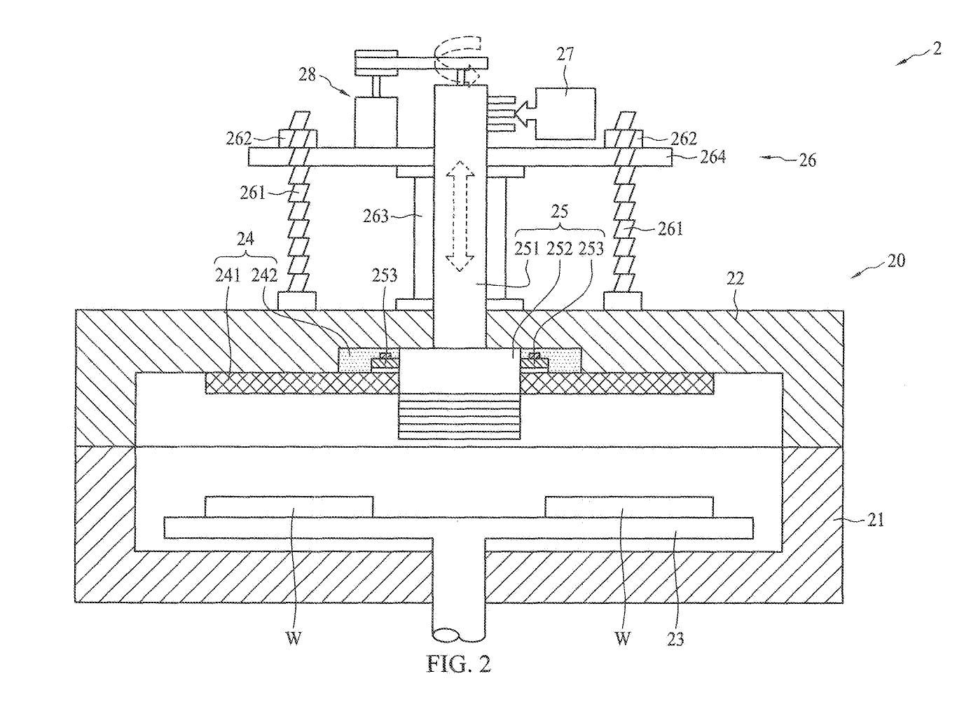

FIG. 2 is a schematic cross-sectional diagram which shows the reactor of a film deposition apparatus in accordance with an embodiment of the present application. As shown in this figure, the reactor 20 of a film deposition apparatus 2 is just an example for the growth of group III-V compound semiconductor. A closed chamber near vacuum is enclosed by chamber walls 21 and a chamber lid 22. A substrate sustaining member 23 is disposed within the chamber, and is used to carry and hold at least one substrate W. A ceiling (i.e. an opposing face member) 24 is disposed opposing to the substrate sustaining member 23. A gas injector 25 is disposed at the center of the chamber lid 22.

The ceiling 24 comprising a plate 241 and an engagement portion 242 used to contain and be interlocked with the fixation portions 252 of the gas injector 25. The plate 241 is combined with the engagement portion 242. The gas injector 25 comprises a gas passage portion 251 capable of delivering source gases of groups III and V, a flow injection portion 252 in communication with the gas passage portion 251, and a plurality of fixation portions 253 disposed on the flow injection portion 252. The gas injector 25 horizontally jets the gasses above a substrate W for mixing. A film is then deposited on each substrate W through physical or chemical reactions induced by heating.

The film deposition apparatus 2 further comprises a position fixing mechanism 26. The position fixing mechanism 26 includes a joint fixing seat 264 combined with the gas injector 25, a moving part 262 mounted to the joint fixing seat 264, and a driving part 261 letting the moving part 262 have a linear movement. In this embodiment, the gas passage portion 251 and the joint fixing seat 264 are combined with each other. The moving part 262 may be a screw nut or a ball screw nut.

Moreover, the driving part 261 may be leading crew or ball leading screw. That is, the moving part 262 is driven to have a linear movement by the rotation or displacement of the driving part 261. The position fixing mechanism 26 further comprises a bush 263 for the gas passage portion 251 to relatively slide therein. The bush 263 is mounted to the reactor 20 outside. For example, it is disposed on the upper surface of the reactor 20.

The film deposition apparatus 2 further comprises a rotation mechanism 28. The rotation mechanism 28 drives the gas passage portion 251 to rotate. This mechanism may further include a step motor, a timing belt and a belt wheel, but the application is not limited to the embodiment. When the gas passage portion 251 rotates, the flow injection portion 252 of the gas injector 25 and the fixation portions 253 on it accordingly rotate around the center line (the center line of the gas passage portion 251 and flow injection portion) to stop at specific locations. Therefore, the fixation portions 253 align with the engagement portion 242 inside. Afterward, the gas injector 25 is slightly lifted so as to let the fixation portions 253 engage with the engagement portion 242.

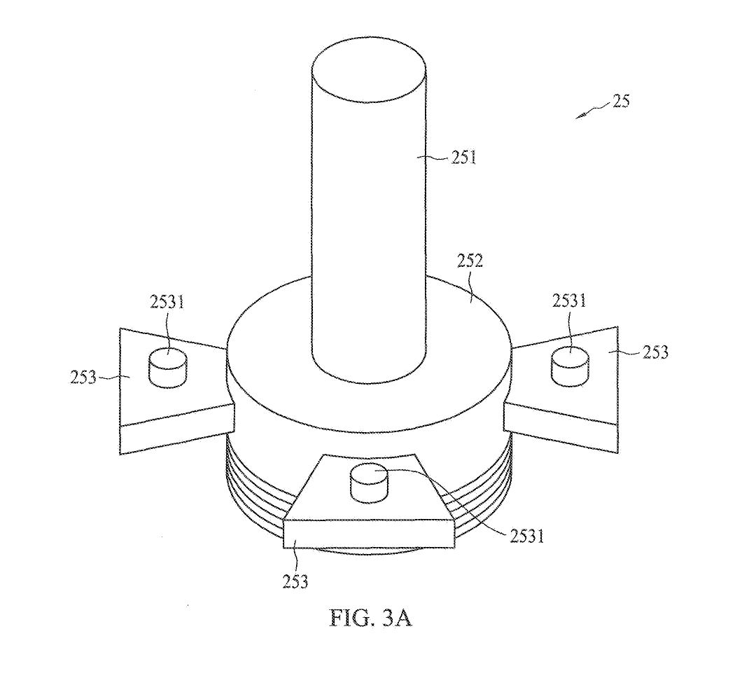

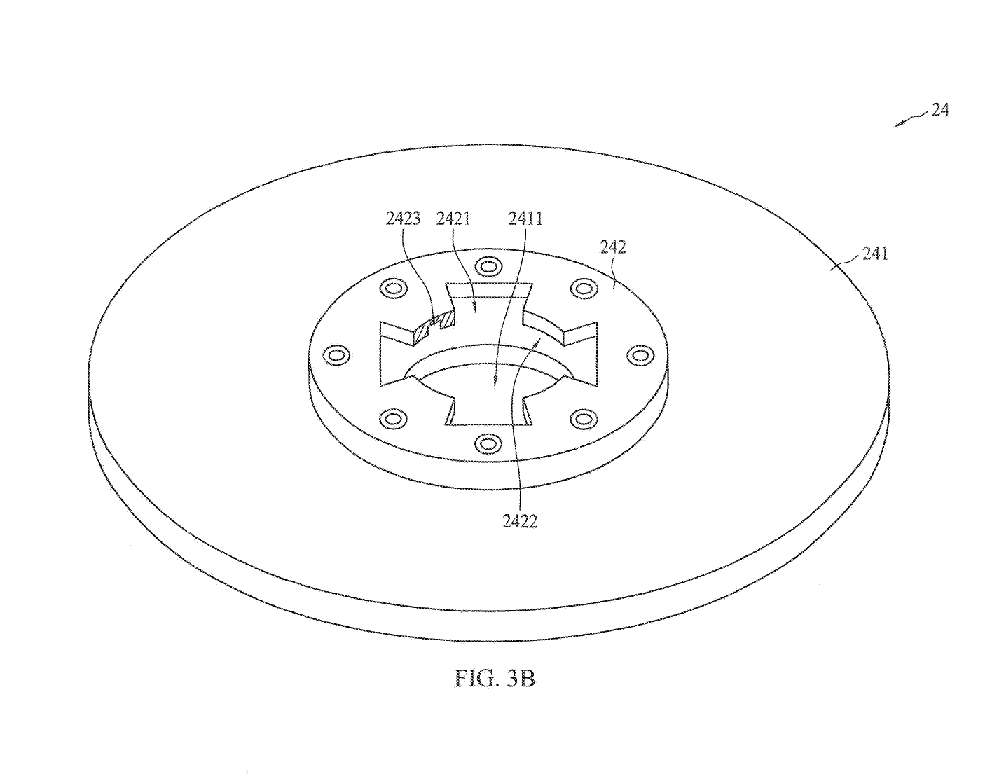

FIG. 3A illustrates a schematically perspective diagram of the gas injector as shown in FIG. 2. The gas injector 25 comprises a gas passage portion 251, a flow injection portion 252, and a plurality of fixation portions 253. The plurality of fixation portions 253 are radially protruded from the perimeter of the flow injection portion 252. The fixation portions 253 are arranged on the circumference of the upper portion of the flow injection portion 252 in a manner that they are respectively disposed at symmetrical (even number) locations or at locations which equally divide its circumference (odd number). The lower portion of the flow injection portion 252 downward extends out from the plate 241 (as shown in FIG. 2), and injects the foregoing several kinds of source gases. There is at least one first positioning member 2531 disposed on the upper surface of each of the fixation portions 253. In this embodiment, the first positioning member 2531 may be a pin or a latch.

The ceiling 24 is mutually engaged with the gas injector 25 as shown in FIG. 3, a schematically perspective diagram. The ceiling 24 comprises a plate 241 and an engagement portion 242. The engagement portion 242 is combined with the plate 241. The material of the plate 241 may be quartz. The engagement portion 242 includes an opening 2421 and a compartment 2422 formed between the engagement portion 242 and the plate 241. The plurality of fixation portions 253 enter through the opening 2421 and is received within the compartment 2422 at corresponding locations after rotation. A plurality of second positioning members 2423 matched with the first positioning members are disposed on the upper wall of the compartment 2422. In this embodiment, each of the second positioning members 2423 may be a location hole or a groove allowing a relative sliding motion on it. There is a trough hole 2411 at the center of the plate 241, and the trough hole 2411 allows a lower portion of the flow injection portion 252 to pass therein.

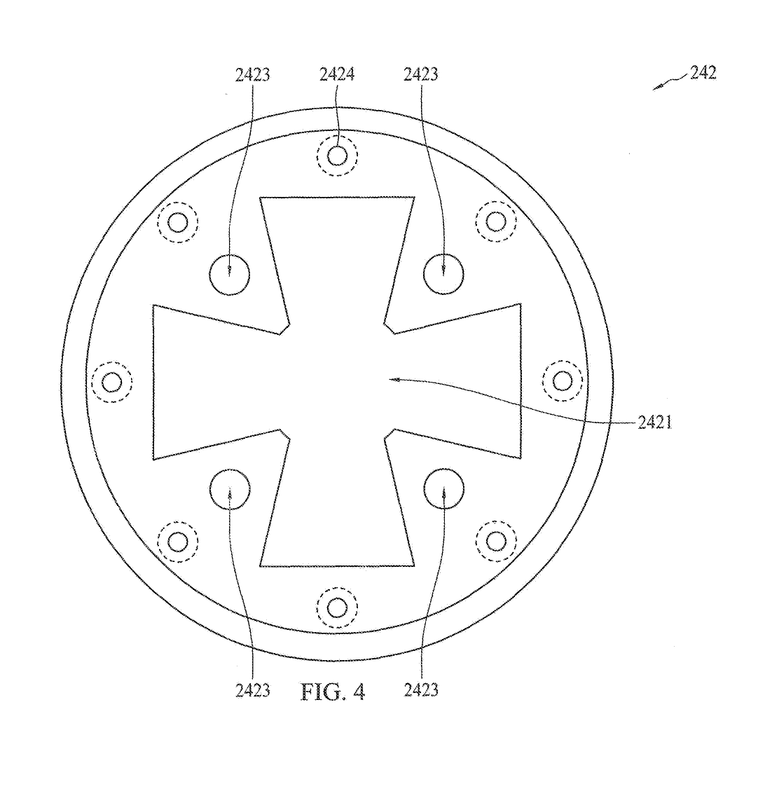

FIG. 4 is a top view of the engagement portion as shown in FIG. 3B. There are a plurality of counterbores 2424 disposed around the engagement portion 242. Screws may be disposed in the counterbores 2424, and are used to combined with the plate 241. The opening 2421 of the engagement portion 242 is sized to match the flow injection portion 252 and the protruded fixation portions 253. The second positioning members 2423 are evenly arranged between the two extended trapezoid slot of the radial opening 2421.

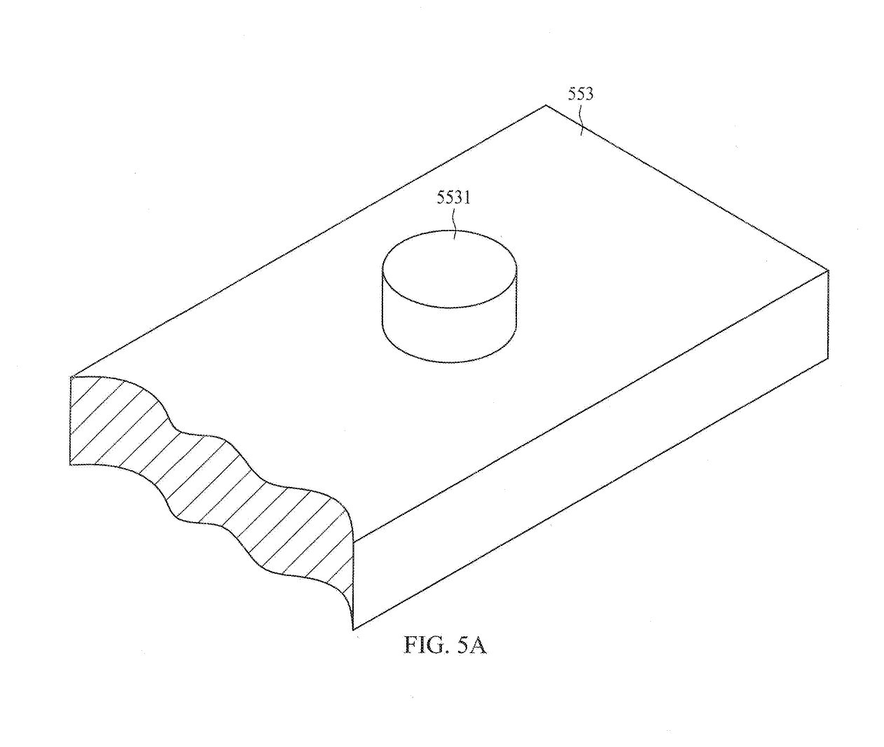

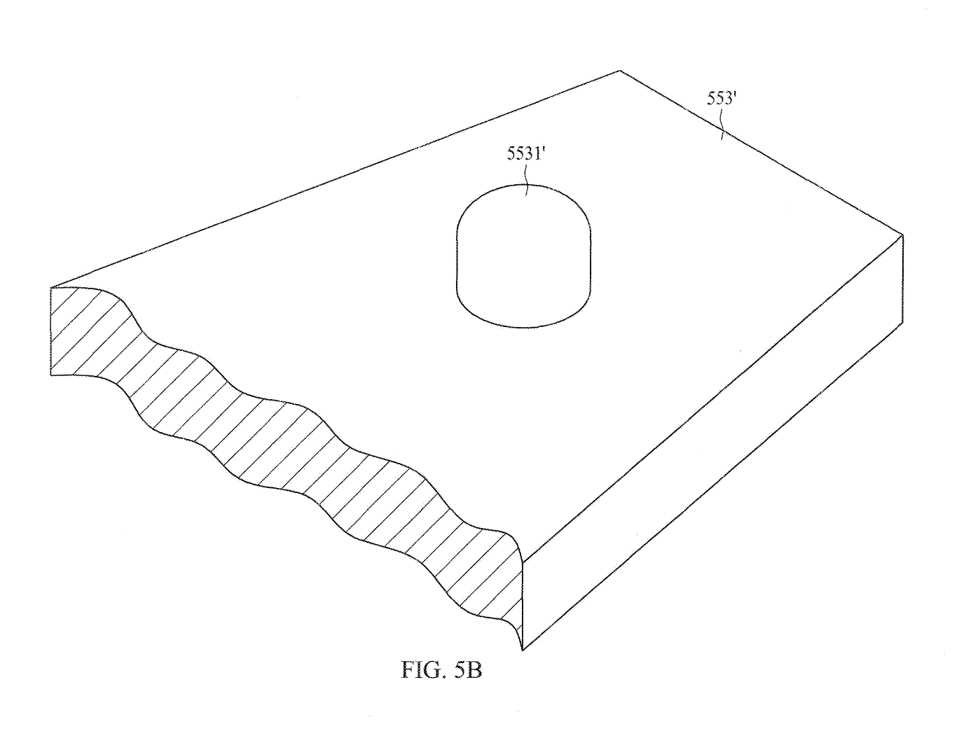

FIG. 5A and FIG. 5B illustrate schematically perspective diagrams of a fixing portion in accordance with another embodiments of the present invention. As shown in FIG. 5, the shape of fixation portions 553 may be a rectangular, but it is not limited to this. The shape also may be a square, arc or trapezoid. At least one first fixing member 5531 is disposed on the upper surface of each fixation portion 553. The embodiment in FIG. 3A shows the fixation portion 553 as a trapezoid.

The low side connected to the flow injection 252 is narrower than the upper side. As shown in FIG. 5B, the fixation portions 553′ is also trapezoid, and the low side connected to the flow injection 252 is wider than the upper side. Similarly, at least one first fixing member 5531′ is disposed on its upper surface.

The foregoing embodiments of the invention have been presented for the purpose of illustration. Although the invention has been described by certain preceding examples, it is not to be construed as being limited by them. They are not intended to be exhaustive, or to limit the scope of the invention. Modifications, improvements and variations within the scope of the invention are possible in light of this disclosure.

What is claimed is:

1. An assembly of a gas injector and a ceiling for semiconductor processes, the assembly comprising:
a gas injector comprising:
a gas passage portion;
a flow injection portion in communication with the gas passage portion; and
a plurality of fixation portions disposed on the flow injection portion;
a ceiling comprising:
an engagement portion containing and interlocked with the fixation portions; and
a plate combined with the engagement portion.

2. The assembly of a gas injector and a ceiling for semiconductor processes according to claim 1, wherein each of the plurality of fixation portions includes a first positioning member and the engagement portion includes a plurality of second positioning members matched with the first positioning members.

3. The assembly of a gas injector and a ceiling for semiconductor processes according to claim 2, wherein each of the first positioning members is one of a location pin and a location hole, and each of the second positioning members is another.

4. The assembly of a gas injector and a ceiling for semiconductor processes according to claim 1, wherein the engagement portion includes an opening and a compartment formed between the engagement portion and the plate, and the plurality of fixation portions enter through the opening and is received within the compartment at corresponding locations after rotation.

5. The assembly of a gas injector and a ceiling for semiconductor processes according to claim 1, wherein there is a trough hole at the center of the plate, and the trough hole allows a portion of the flow injection portion to pass therein.

6. The assembly of a gas injector and a ceiling for semiconductor processes according to claim 1, wherein the plurality of fixation portions are radially protruded from the perimeter of the flow injection portion.

7. The assembly of a gas injector and a ceiling for semiconductor processes according to claim 6, wherein the opening of the engagement portion is sized to match the flow injection portion and the protruded fixation portions.

8. The assembly of a gas injector and a ceiling for semiconductor processes according to claim 1, wherein the fixation portions are trapezoid, rectangular, square, or arc.

9. A film deposition apparatus for semiconductor processes comprising:
a reactor,
a gas injector comprising:
a gas passage portion;
a flow injection portion in communication with the gas passage portion; and
a plurality of fixation portions disposed on the flow injection portion;
a ceiling adjacent to an upper wall surface of the inner of the reactor, comprising:
an engagement portion containing and interlocked with the fixation portions; and
a plate combined with the engagement portion.

10. The film deposition apparatus for semiconductor processes according to claim 9, wherein each of the plurality of fixation portions includes a first positioning member and the engagement portion includes a plurality of second positioning members matched with the first positioning members.

11. The film deposition apparatus for semiconductor processes according to claim 10, wherein each of the first positioning members is one of a location pin and a location hole, and each of the second positioning members is another.

12. The film deposition apparatus for semiconductor processes according to claim 9, wherein the engagement portion includes an opening and a compartment formed between the engagement portion and the plate, and the plurality of fixation portions enter through the opening and is received within the compartment at corresponding locations after rotation.

13. The film deposition apparatus for semiconductor processes according to claim 9, wherein there is a trough hole at the center of the plate, and the trough hole allows a portion of the flow injection portion to pass therein.

14. The film deposition apparatus for semiconductor processes according to claim 9, wherein the plurality of fixation portions are radially protruded from the perimeter of the flow injection portion.

15. The film deposition apparatus for semiconductor processes according to claim 9, wherein the opening of the engagement portion is sized to match the flow injection portion and the protruded fixation portions.

16. The film deposition apparatus for semiconductor processes according to claim 9, further comprising a position fixing mechanism, the position fixing mechanism comprising:
a joint fixing seat combined with the gas injector,
a moving part mounted to the joint fixing seat; and
a driving part letting the moving part have a linear movement.

17. The film deposition apparatus for semiconductor processes according to claim 16, wherein the positioning fixing mechanism further comprises a bush for the gas passage portion to relatively slide therein, and the bush is mounted to the reactor outside.

18. The film deposition apparatus for semiconductor processes according to claim 9, further comprising a rotation mechanism driving the gas injector to rotate so as to engage the plurality of fixation portions with the engagement portion.

19. The film deposition apparatus for semiconductor processes according to claim 9, wherein the fixation portions are trapezoid, rectangular, square, or arc.
